(19) United States
(12) Patent Application Publication
(10) Pub. No.: US 2011/0181789 A1
(43) Pub. Date: Jul. 28, 2011

(54) VOLUME ADJUSTMENT DEVICE AND VOLUME ADJUSTMENT METHOD

(75) Inventor: Hayato Nishimura, Fukaya-shi (JP)

(73) Assignee: KABUSHIKI KAISHA TOSHIBA, Tokyo (JP)

(21) Appl. No.: 12/961,943

(22) Filed: Dec. 7, 2010

(30) Foreign Application Priority Data
Jan. 28, 2010 (JP) 2010-016234

(51) Int. Cl. H03G 3/00; H04N 5/50

(52) U.S. Cl. 348/731; 381/107; 348/E05.096

(57) ABSTRACT

According to one embodiment, a volume adjustment device includes: a playback module configured to select a desired input source from among a plurality of sound input sources for each of which a volume is settable, and to play back the selected input source; and a storage module configured to store a volume at the time of an immediately preceding playback for each of the sound input sources, wherein the playback module controls a volume after switching among the sound input sources based on the value stored in the storage module.

### CROSS-REFERENCE TO RELATED APPLICATION(S)

This application is based upon and claims the benefit of priority from Japanese Patent Application No. 2010-016234, filed on Jan. 28, 2010, the entire contents of which are incorporated herein by reference.

### FIELD

Embodiments described herein relate generally to a volume adjustment device and a volume adjustment method.

### BACKGROUND

In recent years, a TV receiver is provided with a function of playing back a movie content and a music content stored in an external device. When such content is played back at the same volume level at which TV programs are watched, the volume may be so low that the sound is difficult to catch, and the user may have to turn up the volume. Further, when returned from the content playback to the normal (TV program) watching with the volume unchanged, the volume may be higher than expected.

For example, when the TV receiver is functioning as a digital media renderer, since the volume of the TV receiver can be controlled from a digital media controller such as a personal computer, the volume of the TV receiver may be set to an intended level from another apparatus such as a personal computer.

In JP-H09-037174-A, the volume for each of the broadcast stations and external inputs and the correction value thereof are stored in a memory provided in the TV receiver, and the volume is controlled by referring to the correction value at the time of switching. However, JP-H09-037174-A does not disclose how to acquire the correction for each of the broadcast stations and the external inputs.

### BRIEF DESCRIPTION OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 illustrates an example block diagram of a TV receiver according to an embodiment;

FIG. 2 illustrates a remote control provided with plural keys associated with plural operation input information according to the embodiment;

FIG. 3 illustrates an example manner of volume adjustment according to the embodiment;

FIG. 4 illustrates the operation of FIG. 3, in view of FIG. 1; and

FIG. 5 illustrates an example manner of volume adjustment according to another embodiment.

### DETAILED DESCRIPTION

In general, according to one embodiment, a volume adjustment device includes: a playback module configured to select a desired input source from among a plurality of sound input sources for each of which a volume is settable, and to play back the selected input source; and a storage module configured to store a volume at the time of an immediately preceding playback for each of the sound input sources, wherein the playback module controls a volume of after switching among the sound input sources based on the value stored in the storage module.

Hereinafter, embodiments will be described.

### First Embodiment

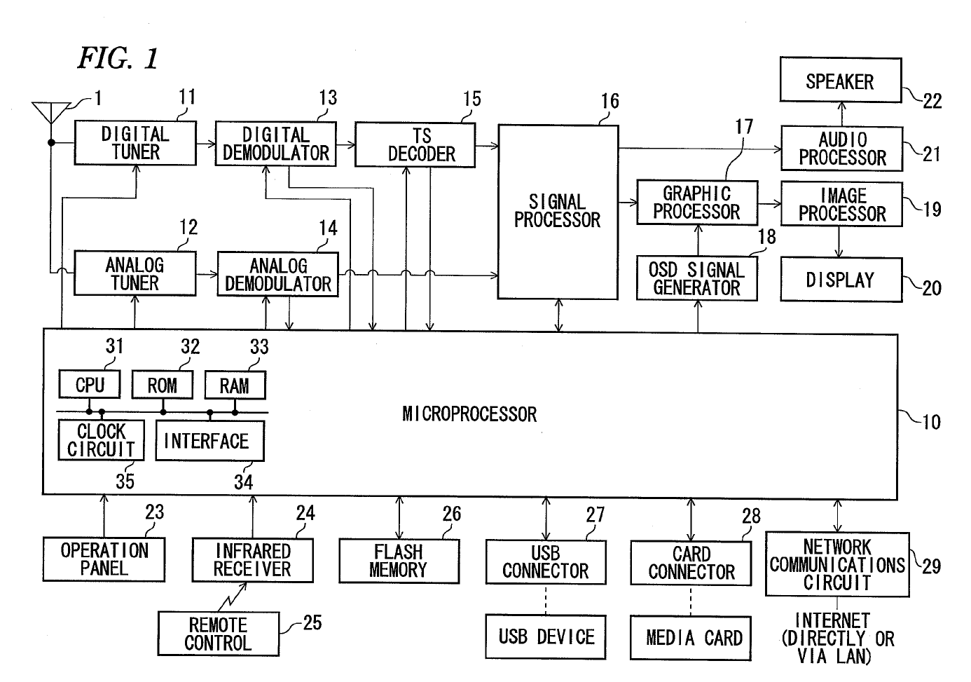

A first embodiment will be described with reference to FIGS. 1 to 4.

First, a TV receiver according to the embodiment will be described with reference to FIG. 1.

FIG. 1 illustrates an example block diagram of the TV receiver according to the embodiment. This TV receiver is capable of receiving an analog terrestrial broadcast wave and digital BS/CS/terrestrial broadcast waves, and is provided with a microprocessor 10, a digital tuner 11, an analog tuner 12, a digital demodulator 13, an analog demodulator 14 and a TS decoder 15.

The digital BS/CS/terrestrial broadcast waves are received by an antenna 1, and the reception signal is supplied to the digital tuner 11. Likewise, the analog terrestrial broadcast wave is received by the antenna 1, and the reception signal is supplied to the analog tuner 12. The digital tuner 11 and the analog tuner 12 employ a phase-locked loop (PLL) method, and are used for selecting a desired broadcast wave while specifying reception parameters such as the center frequency and the bandwidth through control by the microprocessor 10.

For example, in the digital terrestrial broadcasting in Japan, the reception signal of the broadcast wave of the channel selected by the digital tuner 11 is supplied successively to the digital demodulator 13 and the TS decoder 15 employing orthogonal frequency division multiplexing (OFDM), and is demodulated and decoded into digital video and audio signals thereby. The reception signal selected by the analog tuner 12 is supplied to the analog demodulator 14, and is demodulated into analog video and audio signals thereby.

This TV receiver is further provided with a signal processor 16, a graphic processor 17, an on-screen display (OSD) signal generator 18, an image processor 19, a display 20, an audio processor 21, a speaker 22, an operation panel 23, an infrared receiver 24, a remote control 25, a flash memory 26, a universal serial bus (USB) connector 27, a card connector 28 and a network communications circuit 29. The signal processor selectively performs given digital signal processings on the digital video signal and audio signal from the TS decoder 15, and outputs the processed signals to the graphic processor 17 and the audio processor 21, respectively. Moreover, the signal processor 16 selectively digitizes the analog video signal and audio signal from the analog demodulator 14, performs given digital signal processings on the digitized video signal and audio signal, and outputs the processed signals to the graphic processor 17 and the audio processor 21, respectively.

The graphic processor 17 outputs the digital video signal by selectively superimposing an OSD signal generated by the OSD signal generator 18 on the digital video signal outputted from the signal processor 16. The image processor 19 performs a conversion such as a size adjustment on the digital video signal outputted from the graphic processor 17 so as to be adapted to the display 20. The display 20 displays the image corresponding to the video signal outputted from the image processor 19. The audio processor 21 performs a conversion such as a volume adjustment so as to be adapted to the speaker 22, on the digital audio signal outputted from the signal processor 16. The speaker 22 plays back the sound corresponding to the audio signal outputted from the audio processor 21.

The microprocessor 10 receives the operation information from the operation panel 23 or the operation information sent out from the remote control 25 and received by the infrared receiver 24, and controls components to reflect the operation information. Here, the operation panel or a keyboard 23 and the remote control 25 correspond to an operation module that functions as a user interface. As shown in FIG. 1, the microprocessor 10 includes: a central processing unit (CPU) 31 that performs various processings and controls, a read only memory (ROM) 32 that holds a control program for the CPU 31 and various initial data; a random access memory (RAM) 33 that provides a work area for temporarily storing the input and output information of the CPU 31; an interface 34 for inputting and outputting the setting information and the control information for each component through an I2C bus or the like; and a clock circuit 35 corrected according to the time information and the date information obtained via a broadcast wave or a network.

The USB connector 27 is provided for connection with various USB devices. The card connector 28 is provided for connection with various media cards. The network communications circuit 29 is connected to the Internet directly or via a local area network (LAN). When the time information is obtained from a broadcast wave, it is fetched by the microprocessor 10 from a signal received by the antenna 1. When basic data such as the time information, the weather and fortunetelling is obtained from a network, it is fetched by the microprocessor 10 from the network communications circuit 29.

In the flash memory 26 as a nonvolatile memory, BGM (preinstalled BGM) and various registration information used for playing back the BGM may be prestored by the manufacturer prior to the shipment of the TV receiver.

By externally connecting a USB device (memory, etc.) or a media card to the USB connector 27 or the card connector 28, movies, pictures and music data can be read out therefrom.

When a USB memory is connected to the USB connector 27 or a media card is connected to the card connector 28, the microprocessor 10 may fetch photo image stored in the USB memory or the media card and may display the image on the display 20 through the processings by the signal processor 16, the graphic processor 17 and the image processor 19, thereby implementing a photo viewer function or a photo frame function, for example.

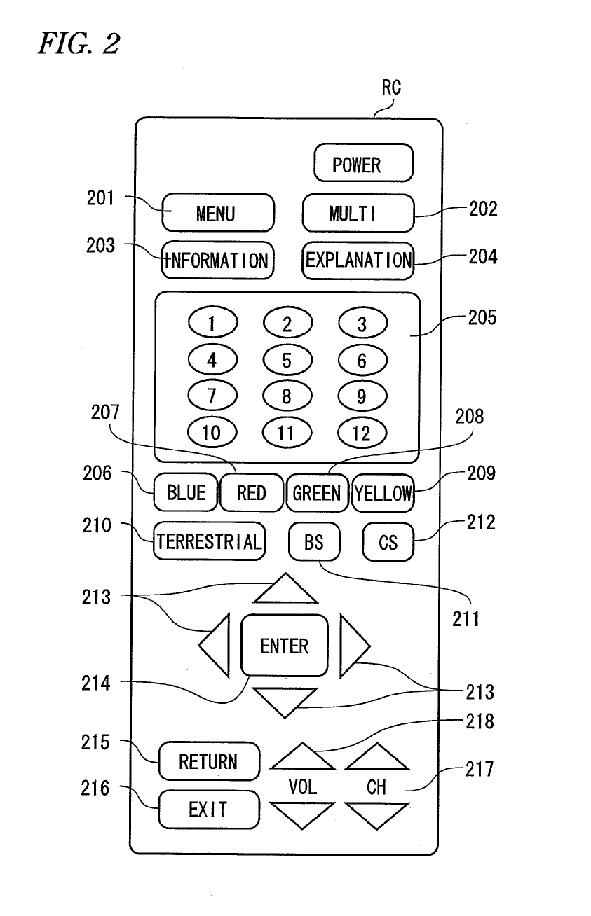

Next, plural keys provided on a remote control RC that outputs the operation input information received by the infrared receiver 24 described with reference to FIG. 1 will be described by using FIG. 2.

FIG. 2 illustrates the remote control RC provided with plural keys associated with plural operation input information, respectively, as the remote control 25.

The user operates the TV receiver by pressing a specific one of the plural keys provided on the remote control RC so that the operation input information associated with the pressed key is outputted from the remote control RC. The remote control RC outputs the operation input information to the TV receiver by using infrared rays or the like.

A menu key 201 is for displaying/dismissing various menu screens on the display 20.

A multi key 202 is for displaying/dismissing a multi screen on the display 20.

An information key 203 is for displaying/dismissing the program-related information of programs related to images presented on the multi screen.

An explanation key 204 is for displaying/dismissing the program explanation information explaining the contents of the program related to an image selected from among the plural images presented on the multi screen.

Numeric keys “1” to “12” of channel selection keys 205 are for receiving specific channels. When the multi screen is displayed, specific numeric keys of the channel selection keys 205 serve as keys for directly changing the number of image presentation areas of the multi screen. It is possible to associate the reception of a specific channel or the number of image presentation areas of the multi screen with each numeric key.

A blue key 206, a red key 207, a green key 208 and a yellow key 209 as color keys are assigned as keys for directly changing the number of image presentation areas of the multi screen when the multi screen is displayed.

A terrestrial broadcast key 210 is a broadcast wave selection key for selecting the reception of digital terrestrial broadcasting. A BS key 211 is a broadcast wave selection key for selecting the reception of BS broadcasting. A CS key 212 is a broadcast wave selection key for selecting the reception of CS broadcasting. By the pressing of these keys, the TV receiver receives a program of the broadcast wave corresponding to the pressed key by using the associated tuner and processing block.

Direction keys 213 are for moving a focus emphasizing a selected image presentation area in the multi screen.

An enter key 214 is for replacing a specific image selected from among the plural images presented on the multi screen, with an image in a given area of the multi screen.

A return key 215 and an exit key 216 are for dismissing the multi screen from a display device 61.

Channel up and down keys 217 include a channel up key for changing the channel in ascending numeric order and a channel down key for changing the channel in descending numeric order. The channel changes in ascending and descending numeric orders are performed in the order of channel number among the receivable channels or the channels that are set so as to be selected.

Volume up and down keys 218 include a volume up key for turning up the volume and a volume down key for turning down the volume. The volume tuning up and down is performed on the sound input source such as the channel being received.

While the unit of the sound input source may be a radio wave broadcast or an individual IP broadcast service as described later, it may be a channel or an individual program.

For media such as DVDs, the unit may be a content (title).

Further, by using a technology of making a distinction between a music part and the remaining part in a program or a title through a broadcast and its recording and a medium, those may be used as the units of different sound input sources based on a selection setting or the like using a menu key preferred by the user.

Other keys may be provided on the remote control RC. Keys equivalent to the keys provided on the remote control RC may be also provided on the operation panel 23.

By pressing a respective key provided on the remote control RC or the like, the user can operate the TV receiver so as to perform plural operations such as the reception of a program of a specific channel, the display/dismissal of the multi screen, the change of the number of images presented on the multi screen, the selection of a specific image on the multi screen and the replacement of images within the multi screen.

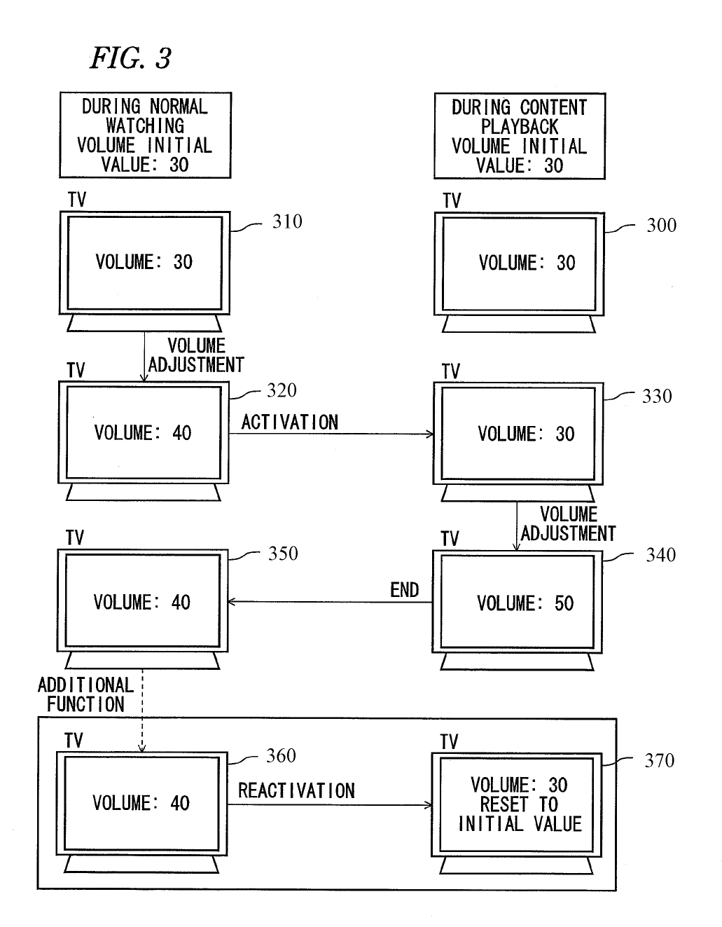

FIG. 3 illustrates an example manner of volume adjustment according to the embodiment.

In FIG. 3, the volume settings are stored separately for during normal (TV program) watching and for during the playback of a movie content or a music content other than a TV program.

300: It is indicated that when a certain content is played back, the volume level is 30 as the initial value (default value).

310: For example, a certain broadcast (in the case of the multi screen, one broadcast thereof) is watched at volume level 30.

320: Then, as the volume adjustment through the operation panel 23 or the remote control 25, the user turns up the volume level to 40.

330: Then, when a certain content is activated for playback, the content is played back at volume level 30 which is the initial value of the volume for content playback.

340: Then, as the volume adjustment through the operation panel 23 or the remote control 25, the user turns up the volume level to 50.

350: Then, when the playback of the certain content is ended, the TV receiver is brought to a condition where the certain broadcast can be watched again at volume level 40.

360 and 370: Then, when the certain content is reactivated for playback, the content is played back at volume level 30. The content may be played back at volume level 50 by an interactive setting using the menu key 201 of the remote control RC or the like. As another method, the volume for during the normal watching may be continuously used as the volume at the start of the content playback. In this case, the volume may be freely adjusted during the content playback. When the content playback is ended, the volume is returned to the volume at the start of the content playback, that is, for during the normal watching.

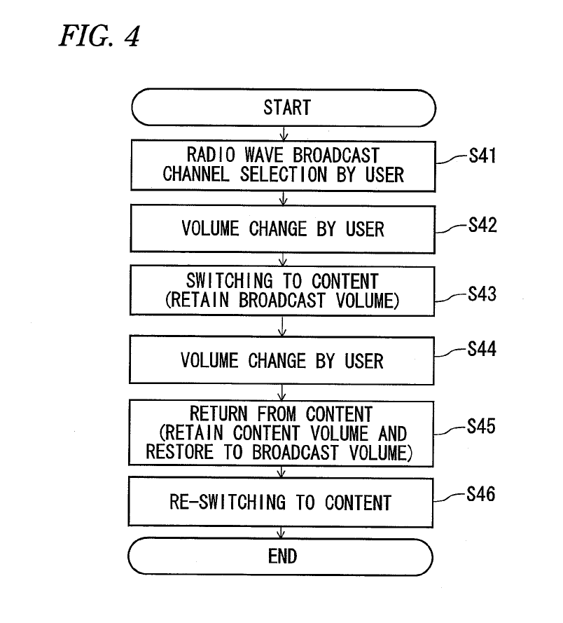

FIG. 4 illustrates the operation of FIG. 3, in view of FIG. 1.

Step S41 (selection of a radio wave broadcast channel): Receiving the operation information from the operation panel 23 corresponding to the broadcast channel selection or the operation information sent out from the remote control 25 and received by the infrared receiver 24 based on the user's operation, the microprocessor 10 controls the channel selection by the digital tuner 11 or the analog tuner 12 to reflect the operation information. Moreover, the microprocessor 10 operates the audio processor 21 via the signal processor 16, for example, so that a certain broadcast can be watched at volume level 30, and performs output to the speaker 22.

Step S42 (volume change): Then, as the volume adjustment through the operation panel 23 or the remote control 25, similarly to step S41, the microprocessor 10 operates the audio processor 21 via the signal processor 16 so that the volume level of the broadcast is turned up to 40, and performs output to the speaker 22.

Step S43 (switching to a content): Receiving the operation information indicating the activation of a content, the microprocessor 10 controls the activation of the content. Moreover, the microprocessor 10 operates the audio processor 21 via the signal processor 16 so that the content activation can be watched at volume level 30 which is the initial value of the volume, and performs output to the speaker 22. At the time of this switching, the volume level that is set lastly at step S42 is stored, for example, in the RAM 33. Further, by storing the volume level, for example, in the ROM 32 or another nonvolatile memory, the volume level can be used as the initial value of the volume after the power-on of the apparatus.

Step S44 (volume change): Then, as the volume adjustment through the operation panel 23 or the remote control 25, similarly to step S42, the microprocessor 10 operates the audio processor 21 via the signal processor 16 so that the volume level of the broadcast is turned up to 50, and performs output to the speaker 22.

Step S45 (return from the content): Receiving the operation information indicating the end of the content, the microprocessor 10 controls the end of the content. Moreover, the microprocessor 10 again controls the channel selection by the digital tuner 11 or the analog tuner 12 as described above so that the TV receiver is brought to the condition where the audio processor 21 is operated via the signal processor 16 so that watching can be performed at volume level 40 which is the previous set value of the volume and output is made to the speaker 22. At the time of this switching, the volume level that is set lastly at step S44 is stored, for example, in the RAM 33.

Step S46 (re-switching to a content): Receiving the operation information indicating the activation of a content, the microprocessor 10 controls the activation of the content. Moreover, the microprocessor 10 operates the audio processor 21 via the signal processor 16 so that the content activation can be watched at volume level 30 which is the initial value of the volume, and performs output to the speaker 22.

Even if the user changes the volume to an arbitrary value during the playback of a movie content or a music content as shown in FIG. 3, when the user returns to the normal watching, the volume is returned to the value that is set lastly during the normal watching. Thereby, even if the volume is turned up for a movie content or a music content having a low volume, when returned to the normal watching, the sound output with the unintentional volume can be prevented. Since the volume level at the time of playback depends on the content, the volume of the previous playback may be too high for the next playback. The volume level at the time of playback of a movie content or a music content stored in an external apparatus may be reset to the initial value every time the playback function is ended.

### Second Embodiment

A second embodiment will be described with reference to FIGS. 1, 2, 4 and 5. Descriptions of parts common to the first embodiment are omitted.

In the second embodiment, classification in the normal broadcast watching is considered so as to store a volume setting for each IP broadcast service (for example, in units of providers such as acTVila (Trademark)).

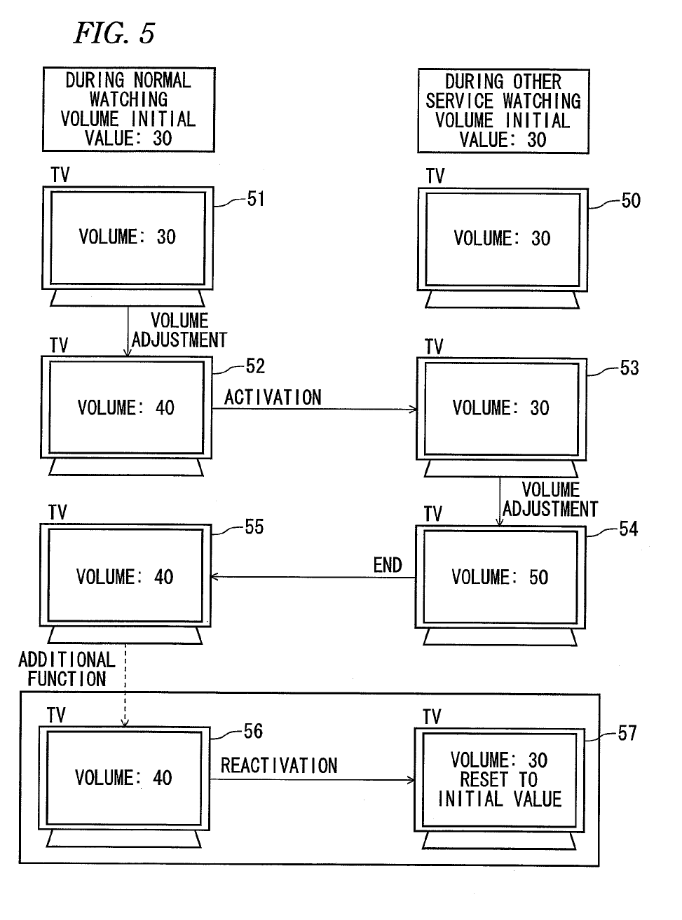

FIG. 5 illustrates an example manner of volume adjustment according to the embodiment.

In FIG. 5, the volume settings are stored separately for during the watching of a certain service (frequently-watched service) and for during the watching of the other service (such as a movie program or a music program other than the frequently-watched service).

50: When a certain program is watched, the volume level is 30 as the initial value (default value).

51: For example, a certain broadcast (in the case of the multi screen, one broadcast thereof) is watched at volume level 30.

52: Then, as the volume adjustment through the operation panel 23 or the remote control 25, the user turns up the volume level to 40.

53: Then, when the other service is activated, the other service can be watched at volume level 30 which is the initial value of the volume thereof.

54: Then, as the volume adjustment through the operation panel 23 or the remote control 25, the user turns up the volume level to 50.

55: Then, when the watching of the other service is ended, the TV receiver is brought to a condition where the certain broadcast can be watched again at volume level 40.

56 and 57: Then, when the other service is reactivated, it is played back at volume level 30. The service may be watched at volume level 50 by an interactive setting using the menu key 201 of the remote control RC or the like.

While switching between IP broadcast services through a network is described in the second embodiment, switching may be made between an IP broadcast service and a radio wave broadcast as in the first embodiment.

### Summary of the Embodiments

In the embodiments, for example, following points are described.

(1) The volume settings are separately stored for during the normal watching (normal TV program watching) and for during the content playback (playback of a movie content or a music content).

(2) Measures similar to those for during the playback of a movie content or a music content stored in an external device are taken for the function associated with IP TV services.

(3) The volume for the playback of a movie content or a music content stored in an external device may be reset to an initial value every time the playback function is ended.

For example, according to the present embodiment, a volume for the normal TV program watching and a volume for the content playback in which a movie content or a music content from the external device is watched or listened to are prestored in a storage device by the volume setting storage method, so that even when the volume is changed in the content playback, the volume is controlled to the set volume value in the storage device when the user returns to the normal TV program watching.

The present invention is not limited to the above-described embodiments, and may be carried out while modified in various other ways without departing from the gist thereof.

Moreover, various inventions may be formed by appropriately combining plural structural elements disclosed in the above-described embodiments. For example, some structural elements may be deleted from the embodiments, and elements of different embodiments may be combined.

According to the embodiments, a volume adjustment device and a volume adjustment method are obtained allowing the user to set a volume for respective sound input source.

What is claimed is:

1. A volume adjustment device comprising:
a playback module configured to select a desired input source from among a plurality of sound input sources for each of which a volume is settable, and to play back the selected input source; and
a storage module configured to store a volume level at the time of a previous playback of the selected input source,
wherein the playback module controls a volume level after switching to play back the selected input source based on the value stored in the storage module.

2. The device of claim 1,
wherein a volume has an initial level, is set to a second level during a playback of a movie content or a music content stored in an external device as the sound input source, and is reset to the initial level when the playback function is ended.

3. The device of claim 2, further comprising
a setting module configured to prevent the resetting to the initial level.

4. The device of claim 1, further comprising
a tuner configured to select a broadcast signal; and
a demodulator configured to receive the broadcast signal and output a sound source,
wherein an output of the receiver is used as the sound input source.

5. A volume adjustment method comprising:
selecting a desired input source from among a plurality of sound input sources for each of which a volume is settable;
playing back the selected input source;
storing a volume level at the time of an immediately preceding playback for each of the sound input sources; and
controlling a volume after switching among the sound input sources based on the stored level.

6. A volume adjustment method comprising:
outputting a first content at a first volume level;
outputting a second content at a second volume level, the second content different from the first content and the second volume level different from the first volume level;
automatically restoring the volume to the first volume level when output of the second content ceases.

7. The method of claim 6, further comprising outputting the first content at a third volume level after outputting the first content at the first volume level and before outputting the second content at the second volume level.

8. The method of claim 6, further comprising outputting the second content at a fourth volume level after outputting the second content at the second volume level and before automatically restoring the volume.

9. The method of claim 6, wherein the first content is of a first type and the second content is of a second type, different from the first type, and wherein automatically restoring the volume to the first volume level occurs when a content of the first type is output after outputting the second content.
